(19) United States
(12) Patent Application Publication
(10) Pub. No.: US 2020/0369486 A1
(43) Pub. Date: Nov. 26, 2020

(54) FLEXIBLE SUBSTRATE ADJUSTING DEVICE

(71) Applicant: INDUSTRIAL TECHNOLOGY RESEARCH INSTITUTE, Hsinchu (TW)

(72) Inventors: Kuo-Hsin HUANG, Zhubei City (TW); Yu-Lin HSU, Tainan City (TW); Chien-Hung LIN, Xiushui Township (TW); Hsin-Yun HSU, Zhudong Township (TW)

(73) Assignee: INDUSTRIAL TECHNOLOGY RESEARCH INSTITUTE, Hsinchu (TW)

(21) Appl. No.: 16/727,343

(22) Filed: Dec. 26, 2019

Related U.S. Application Data
(60) Provisional application No. 62/852,324, filed on May 24, 2019.

(30) Foreign Application Priority Data
Nov. 5, 2019 (TW) 108140065

(51) Int. Cl. B65H 23/038; B65H 23/188; H01L 51/00

(52) U.S. Cl. CPC B65H 23/038; H01L 51/0097; B65H 23/1888

(57) ABSTRACT

A flexible substrate adjusting device includes a substrate transmission mechanism, a pressure roller, and a force applying assembly. The substrate transmission mechanism has a transmission direction for carrying a first surface of a flexible substrate thereon. The pressure roller is disposed on at least one side of a second surface of the flexible substrate in a non-transmission direction. The force applying assembly is connected to the pressure roller and provides the pressure roller with a pressure to the flexible substrate, wherein when the flexible substrate moves in the transmission direction, the pressure roller generates a friction force in the non-transmission direction with the flexible substrate to adjust flatness or position of the flexible substrate.

This application claims the benefits of U.S. provisional application Ser. No. 62/852,324, filed May 24, 2019, and Taiwan application Serial No. 108140065, filed Nov. 5, 2019, the disclosures of which are incorporated by reference herein in its entirety respectively.

### TECHNICAL FIELD

The disclosure relates to a flexible substrate adjusting device.

### BACKGROUND

For flexible substrates, such as OLED (Organic Light-Emitting Diode) substrates, flexible circuit boards, optical films, and the like produced by general roll-to-roll production, a substrate transmission mechanism is used to transport the flexible substrates to the machine. Generally speaking, in order to avoid the processing surface of the flexible substrate from contacting the transmission rollers, the processing surface is only in partial contact with the step rollers for substrate transmission. However, during the transmission of the flexible substrate, due to the tension in the transmission direction, the two sides of the flexible substrate could not be subjected to an average tension. Therefore, the flexible substrate passing through the step rollers may wrinkle or cause defects in the processing surface, and thus the yield rate of the flexible substrate is decreased.

### SUMMARY

According to one embodiment, a flexible substrate adjusting device including a substrate transmission mechanism, a pressure roller, and a force applying assembly is provided. The substrate transmission mechanism has a transmission direction for carrying a first surface of the flexible substrate thereon. The pressure roller is disposed on at least one side of a second surface of the flexible substrate in a non-transmission direction. The force applying assembly is connected to the pressure roller and provides the pressure roller with a pressure to the flexible substrate. When the flexible substrate moves in the transmission direction, the pressure roller generates a friction force in the non-transmission direction with the flexible substrate to adjust flatness or a position of the flexible substrate.

### BRIEF DESCRIPTION OF THE DRAWINGS

FIG. 1A is a schematic diagram of a substrate transmission mechanism according to an embodiment.

FIG. 1B is a schematic diagram of a substrate transmission system according to an embodiment of the disclosure.

FIG. 2A is a front schematic view of a flexible substrate adjusting device according to an embodiment of the disclosure.

FIG. 2B is a top schematic view of a flexible substrate adjusting device according to an embodiment of the disclosure.

FIGS. 3A and 3B are schematic diagrams of the force applying assembly actuating the pressure roller.

FIG. 3C is a schematic diagram of the force applying assembly actuating the pressure roller.

FIG. 4A is a front schematic view of a flexible substrate adjusting device according to an embodiment of the disclosure.

FIG. 4B is a schematic diagram of a roller set according to an embodiment of the disclosure.

FIGS. 5A and 5B are schematic diagrams illustrating embodiments of a single pressure roller, respectively.

FIG. 5C is a schematic diagram showing an embodiment of two pressure rollers arranged in the same direction.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Details are given in the non-limiting embodiments below. It should be noted that the embodiments are illustrative examples and are not to be construed as limitations to the claimed scope of the present disclosure. The same/similar denotations are used to represent the same/similar components in the description below. Directional terms such as above, below, left, right, front or back are used in the following embodiments to indicate the directions of the accompanying drawings, not for limiting the present disclosure.

According to an embodiment of the disclosure, a flexible substrate adjusting device is provided, which could be used to transport flexible substrates produced by roll-to-roll production, and could make the flexible substrates flatten when the flexible substrates are transported on a flat surface wheel or other curved surface wheel. The curved surface wheel is, for example, a vertical step wheel or a curved step wheel, and the flat surface wheel is, for example, a cylindrical wheel without a step.

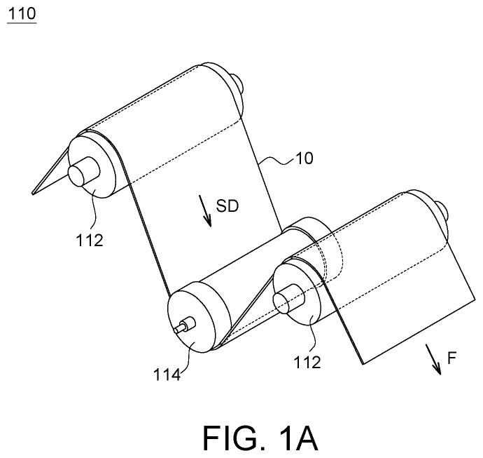

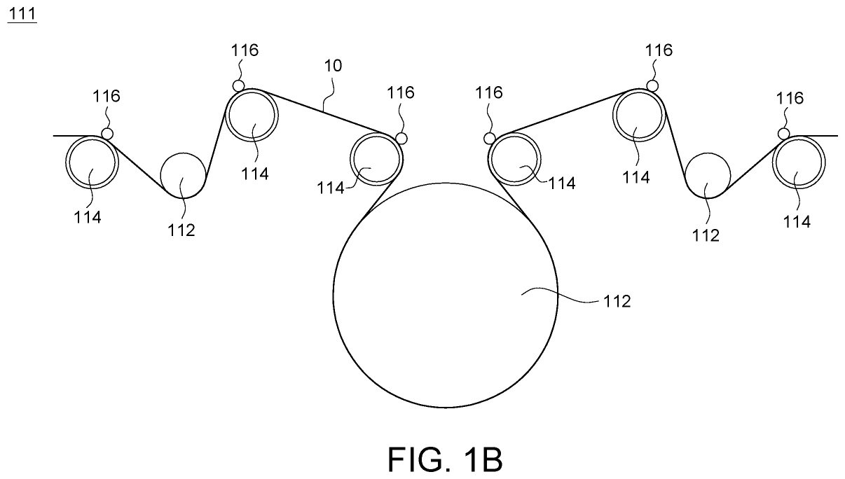

FIG. 1A is a schematic diagram of a substrate transmission mechanism 110 according to an embodiment, and FIG. 1B is a schematic diagram of a substrate transmission system 111 according to an embodiment of the disclosure. As shown in FIG. 1A, the substrate transmission mechanism 110 may be provided with a step wheel 114 between two flat surface wheels 112 to transport the flexible substrate 10 produced by roll-to-roll production, so that the flexible substrate 10 moves along a transmission direction SD. In order to move the flexible substrate 10 along the transmission direction SD, the substrate transmission mechanism 110 applies a predetermined tension F to the flexible substrate 10. In addition, in FIG. 1A, the upper surface of the flexible substrate 10 is a processing surface, and the lower surface of the flexible substrate 10 is a non-processing surface. In order to prevent the processing surface of the flexible substrate 10 produced by the roll-to-roll production from contacting the two flat surface wheels 112 of the substrate transmission mechanism 110, the non-processing surface at the bottom of the flexible substrate 10 and the two flat surface wheels 112 below the flexible substrate 10 are in rolling contact, and the two side areas of the processing surface at the top of the flexible substrate 10 are also in rolling contact with the step wheel 114. Of course, this embodiment is not limited to providing only one step wheel 114, and at least one step wheel 114 may be provided between the two flat surface wheels 112 according to actual needs, and the number thereof is not limited, as shown in the substrate transmission system 111 in FIG. 1B. On the other hand, when both the upper and lower surfaces of the flexible substrate 10 are processing surfaces, or both the upper and lower surfaces of the flexible substrate 10 are non-processing surfaces, all wheels may be provided by step wheels 114 or flat surface wheels 112 according to actual needs. The present disclosure is not limited thereto.

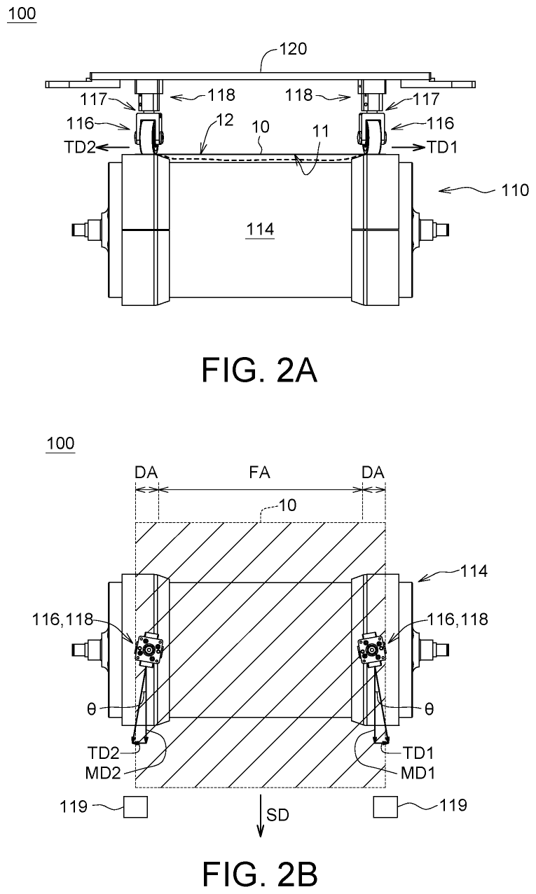

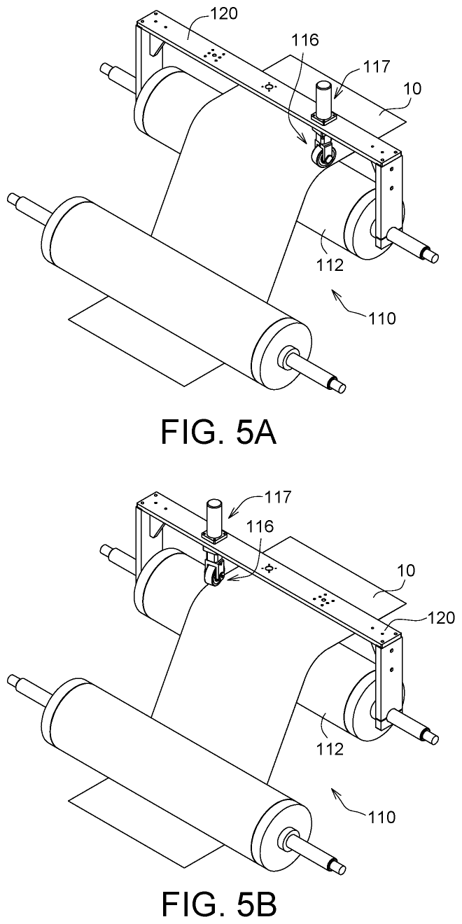

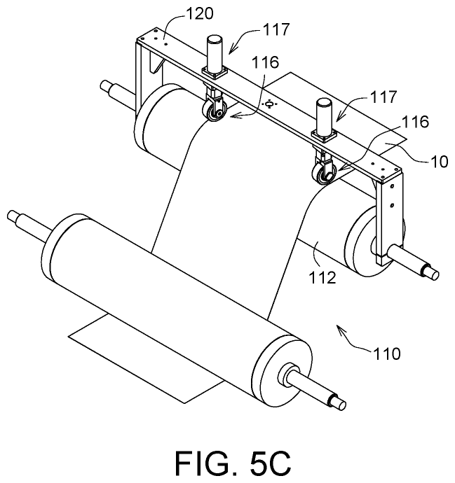

Please refer to FIGS. 2A and 2B, which respectively show a front schematic view and a top schematic view of a flexible substrate adjusting device 100 according to an embodiment of the disclosure. The flexible substrate adjusting device 100 includes a substrate transmission mechanism 110, a set of pressure rollers 116, and a force applying assembly 118. The substrate transmission mechanism 110 may be a step wheel 114 or a flat surface wheel 112 for carrying a first surface 11 of the flexible substrate 10 thereon. The first surface 11 is, for example, a non-processing surface or a processing surface, that is, the first surface 11 of the flexible substrate 10 is supported by the flat surface wheel 112 or the step wheel 114 of the flexible substrate transmission mechanism 110. The pressure rollers 116 are disposed on opposite sides of the flexible substrate 10, that is, opposite sides of a second surface 12 of the flexible substrate 10 in a non-transmission direction. When there is only a single pressure roller 116, the pressure roller 116 may be disposed on a side of the second surface 12 of the flexible substrate 10 in a non-transmission direction, as shown in FIGS. 5A and 5B. The force applying assembly 118 includes a set of force generators connected to the set of pressure rollers 116, so that each of pressure rollers 116 provides a force to the flexible substrate 10. The pressure rollers 116 and the force applying assembly 118 could be locked or fixed on a plate body 120. The plate body 120 may be fixed to the central axis of the substrate transmission mechanism 110 or may be fixed to other bodies.

In one embodiment, the quantity of the pressure rollers 116 may be two, and the quantity of the force applying assembly 118 may be two. The quantity of the force applying assembly 118 and the pressure rollers 116 are the same, but the present disclosure is not limited thereto.

The pressure roller 116 is disposed above the second surface 12 of the flexible substrate 10, and the second surface 12 is, for example, a non-processing surface. That is, the pressure roller 116 may be disposed above the non-processing surface of the flexible substrate 10. Please refer to FIG. 2B. In one embodiment, the left and right sides of the non-processing surface are blank areas DA for rolling contact of the pressure rollers 116, and the middle area is a functional area FA for manufacturing an organic light emitting layer such as an OLED element or other components. The blank area DA is located on the two sides of the functional area FA, and is opposite to the pressure rollers 116. Therefore, in one embodiment, the pressure rollers 116 are disposed on the opposite sides of the second surface 12 of the flexible substrate 10 in the non-transmission direction. It could prevent the pressure rollers 116 from contacting the functional area FA in the middle of the flexible substrate 10, and could flatten the flexible substrate 10 by the friction force provided by the pressure rollers 116 in the non-transmission direction.

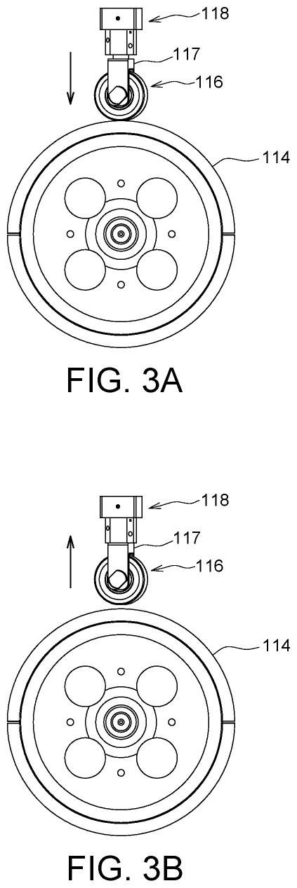

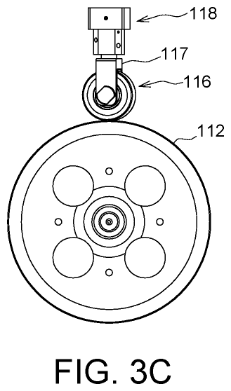

In an embodiment, the force applying assembly 118 includes a set of springs, and the set of pressure rollers 116 could respectively provide a pressure to the flexible substrate 10 through the spring force of the set of springs. In another embodiment, the force applying assembly 118 includes a set of pneumatic cylinders, a set of electromagnetic coils, or a set of motors. The pneumatic cylinders, the electromagnetic coils, and the motors could be actuated by turning on electrical signals to actuate the pressure rollers 116. For example, please refer to FIG. 3A and FIG. 3B, which respectively show schematic diagrams of the force applying assembly 118 actuating the pressure rollers 116. The force applying assembly 118 includes a set of actuators, such as a set of pneumatic cylinders or a set of motors. When the pressure rollers 116 are pushed down or lifted by an actuator, the pressure rollers 116 are in contact with the step wheel 114 or not. On the other hand, the pressure rollers 116 could also be pressed down onto the flat surface wheel 112 via an actuator, as shown in FIG. 3C, the present disclosure is not limited thereto.

All of the flat surface wheel 112, the step wheel 114, and the pressure rollers 116 may be active wheels for driving the flexible substrate 10, or the flat surface wheel 112 and the step wheel 114 are active wheels, and the pressure rollers 116 are passive wheels. Active or passive wheels could be changed to each other according to actual needs.

Please refer to FIG. 2A. When the flexible substrate 10 crosses the central recess region (indicated by a dotted line) of the step wheel 114, the central region of the flexible substrate 10 is pulled down by the tension in the transmission direction SD, so that the flexible substrate 10 could not be flattened at the time of rolling and is easy to produce irregular wrinkles. Referring to FIG. 2B, when the flexible substrate 10 moves in the transmission direction SD, the pressure rollers 116 generate a friction force in a non-transmission direction with the flexible substrate 10 to adjust the flatness of the flexible substrate 10. That is, in addition to the friction force in the transmission direction SD, the flexible substrate 10 also receives the friction force in a non-transmission direction to flatten the flexible substrate 10.

Referring to FIG. 2B, the friction forces in the substrate transmission direction SD are indicated by arrows MD1 and MD2, and the forces in the non-transmission direction are the axial friction forces indicated by arrows TD1 and TD2. The arrows MD1 and MD2 are in the same direction as the substrate transmission direction SD and substantially have the same size, and the directions of the arrows TD1 and TD2 are opposite to each other and the arrows TD1 and TD2 substantially have the same size. The combined force of the arrow MD1 and the arrow TD1 is equal to the rotation pulling force of one pressure roller 116 on the flexible substrate 10, and the combined force of the arrow MD2 and the arrow TD2 is equal to the rotation pulling force of the other pressure roller 116 on the flexible substrate 10. The flexible substrate adjusting device 100 of this embodiment could obtain a proper friction force in a non-transmission direction by controlling the deflection angle θ of the pressure rollers 116 with respect to the substrate transmission direction SD.

Generally, the axial friction forces exerted by the pressure rollers 116 on the flexible substrate 10 are related to the material of the pressure roller, the friction coefficient, the deflection angle θ, and the normal force of the pressure roller perpendicular to the flexible substrate 10. When the same normal force is applied, the lower the hardness of the pressure roller, the greater the amount of deformation of the pressure roller, the greater the area of the flexible substrate 10 contacting the pressure roller, and the greater the axial friction force between the pressure roller and the flexible substrate.

In an embodiment, the pressure rollers 116 may be a soft plastic wheel, a rubber wheel or a rigid wheel. The hardness of the pressure rollers 116 is, for example, between Shore hardness A20 and A60. The normal force of the flexible substrate 10 is, for example, between 5N and 50N.

In addition, the diameter of the pressure rollers 116 may be between 15 mm and 100 mm, and the diameter of the flat surface wheel 112 or the step wheel 114 may be between 50 mm and 220 mm. The step distance between the inner and outer wheel diameters of the step wheel 114 is, for example, about 8 mm. Generally speaking, the tension in the substrate transmission direction SD is related to the diameter and span of the flat surface wheel 112 or the step wheel 114. The greater the diameter and the substrate span of the flat surface wheel 112 or the step wheel 114, the greater the tension in the substrate transmission direction SD. Therefore, the proper tension could be obtained by calculating the friction force of the flat surface wheel 112 or the step wheel 114 on the substrate transmission direction SD.

In addition, the greater the friction coefficient between the pressure roller 116 and the flexible substrate 10, the greater the friction between the pressure roller 116 and the flexible substrate 10, and the greater the axial friction force. In addition, the deflection angle θ of the pressure roller 116 is, for example, between 5 degrees and 45 degrees. The greater the deflection angle θ, the greater the axial friction force.

Please refer to FIGS. 2A and 2B. In one embodiment, the pressure rollers 116 (for example, flat surface wheels) include an angle control unit 117, which could adjust the deflection angle θ of the pressure rollers 116 with respect to the substrate transmission direction SD. The angle control unit 117 could set the deflection angle θ of the pressure roller 116 to a set value, and could keep the axial friction forces of the set of pressure rollers 116 on the opposite sides of the flexible substrate 10 substantially the same.

In another embodiment, the deflection angle θ of the pressure rollers 116 to the flexible substrate 10 or the axial friction forces TD1 and TD2 may also be designed to be different. For example, the axial friction force of one pressure roller 116 on the flexible substrate 10 is greater than the axial friction force of another pressure roller 116 on the flexible substrate 10, or the deflection angle of one pressure roller 116 to the flexible substrate 10 is zero, and the deflection angle of the other pressure roller 116 to the flexible substrate 10 is greater than zero. That is, as long as the deflection angle or the axial friction force of one of the pressure rollers is large enough, the central region of the flexible substrate 10 could be flattened without sagging or irregular wrinkles, and it is not limited to implement the flexible substrate adjusting device 100 of the present disclosure with a set of pressure rollers 116 having the same deflection angle θ.

In addition, the flexible substrate adjusting device 100 of the present disclosure could be used to transport other types of flexible substrates in addition to the flexible substrate 10 produced by roll-to-roll production. The type of the flexible substrate 10 may be, for example, plastic substrates, rubber substrates, paper substrates, ultra-thin glass substrates, or ultra-thin metal substrates.

Furthermore, referring to FIG. 2B, the flexible substrate adjusting device 100 of the present disclosure may further include an edge finding device 119, which is disposed above or below the transmission path of the flexible substrate 10. The edge finding device 119 is, for example, an image type or optical edge position controller used to detect the edge position of the flexible substrate 10 to ensure that the edge position of the flexible substrate 10 does not deviate from the normal transmission path. In one embodiment, the flexible substrate adjusting device 100 is used to flatten the flexible substrate 10. In addition to avoiding wrinkles, the edge position of the flexible substrate 10 could be adjusted by the flexible substrate adjusting device 100 to generate a force perpendicular to the transmission direction, so that the edge of the flexible substrate 10 could be aligned with the edge finding device 119 more accurately, and the flexible substrate 10 could be accurately aligned (web-handled). Therefore, the flexible substrate adjusting device 100 of the above embodiment could reduce the wrinkles of the flexible substrate 10 or adjust the edge position of the flexible substrate 10 to facilitate the processing of the components or circuits on the flexible substrate 10 smoothly.

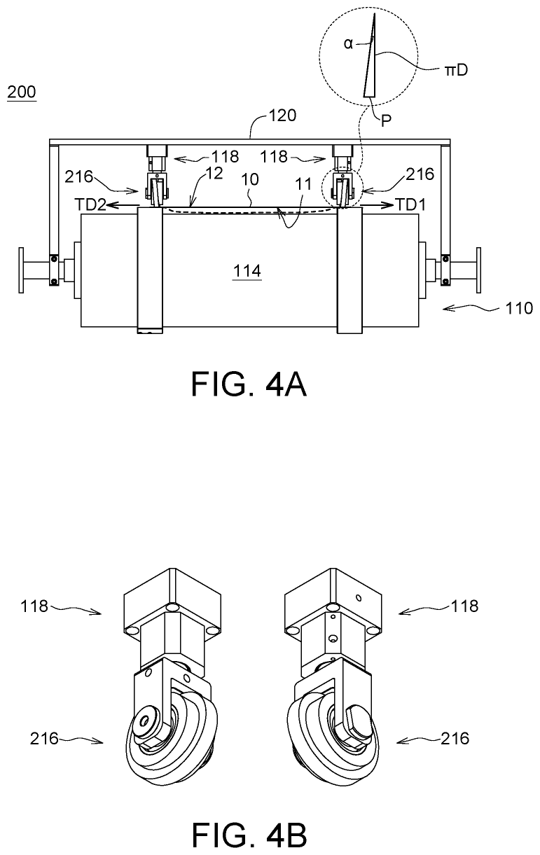

Please refer to FIGS. 4A and 4B, which respectively show a front schematic view of the flexible substrate adjusting device 200 according to an embodiment of the present disclosure and a schematic view of a set of pressure rollers thereof. The components and arrangement of the flexible substrate adjusting device 200 of this embodiment are substantially the same as those of the above-mentioned flexible substrate adjusting device 100. The same representative symbols represent the same components, and the difference is that the pressure rollers of this embodiment are a set of spiral pressure rollers 216 (or a single spiral pressure roller 216), compared with the pressure rollers 116 of the above embodiment, the spiral pressure rollers 216 of this embodiment do not need a deflection angle θ, and therefore no additional angle control unit is required. However, if the spiral pressure roller 216 requires an additional deflection angle θ, an angle control unit may be provided to increase the deflection angle. The operating principle of the spiral pressure rollers 216 is as follows: the force generated in the axial direction when the spiral pressure roller is rotated is used to obtain the friction force in the non-transmission direction (that is, the axial friction force) for flattening the flexible substrate 10. In other words, when the flexible substrate 10 is moved in the transmission direction by the substrate transmission mechanism, the spiral pressure roller 216 is rotated by the pulling force of the flexible substrate 10 to generate the axial force.

Referring to FIG. 4A, the spiral pressure rollers 216 are disposed on two opposite sides of the flexible substrate 10, and are provided with two sets of spirals with opposite rotation directions to flatten the flexible substrate 10 to respective side. The axial distance between two corresponding points of adjacent threads on the spiral pressure roller 216 is pitch. The pitch P is divided by the circumference of the pressure roller (πD, D is the diameter of the pressure roller), and the tangent of the spiral angle α could be obtained. Referring to the partial schematic diagram in FIG. 4A, in one embodiment, the greater the pitch P of the spiral pressure roller 216, the greater the spiral angle α, and the greater the axial friction force of the spiral pressure roller 216 on the flexible substrate 10.

In an embodiment, the spiral angle α is, for example, between 1 degree and 5 degrees or other values.

In one embodiment, the spiral angles α of the set of spiral pressure rollers 216 could be designed to be the same, so as to keep the axial friction forces of the spiral pressure rollers 216 on the opposite sides of the flexible substrate 10 substantially the same. In another embodiment, the spiral angles α of the spiral pressure rollers 216 could also be designed to be different. For example, the spiral angle of one spiral pressure roller 216 is greater than the spiral angle of the other spiral pressure roller 216, or the spiral angle of one pressure roller is zero (i.e., a flat surface wheel), and the spiral angle of the other spiral pressure roller 216 is greater than zero. That is, as long as the spiral angle of one of the pressure rollers is large enough, the central region of the flexible substrate 10 could be flattened without sagging or irregular wrinkles. It is not limited to implement the flexible substrate adjusting device 200 of the disclosure with two spiral pressure rollers with the same spiral angle. In addition, the edge position of the flexible substrate 10 could be adjusted by generating a force perpendicular to the transmission direction by the flexible substrate adjusting device 200, so that the edge of the flexible substrate 10 could be more accurately aligned with the edge finding device 119, so that the flexible substrate 10 could be accurately aligned (web handled). Therefore, the flexible substrate adjusting device 200 of the above embodiment could reduce wrinkles or adjust the edge position of the flexible substrate 10 to facilitate the processing of the components or circuits on the flexible substrate 10 smoothly.

Referring to FIGS. 5A and 5B, a single pressure roller 116 is disposed on one side of the substrate transmission mechanism 110, and an angle control unit 117 is used to adjust the deflection angle of the pressure roller 116 to generate a single-direction axial friction force. In one embodiment, since there is only a single axial friction force, when the pressure roller 116 is applied to the flexible substrate 10, the flexible substrate 10 could be shifted in the axial direction. At the same time, the angle control unit 117 is used to control the deflection direction of the pressure roller 116 (such as change direction inward or outward) to generate an axial offset, which is used for the edge correction and alignment of the flexible substrate 10 so that the flexible substrate 10 could be accurately aligned (web handled). In another embodiment (not shown), the axial friction force of the single spiral pressure roller 216 could also be used to cause the flexible substrate 10 to be axially offset for the edge correction and alignment of the flexible substrate 10. When the alignment of the flexible substrate 10 has been completed, the spiral pressure roller 216 is lifted by the actuator to separate the spiral pressure roller 216 from the flexible substrate 10.

In addition, referring to FIG. 5C, a set of pressure rollers 116 for correcting and aligning the flexible substrate 10 could also be arranged on opposite sides of the substrate transmission mechanism 110 in the same direction, and the angle control unit 117 could control the set of pressure rollers 116 to be offset in the same direction or not, so as to shift the flexible substrate 10 in the axial direction or not. In an embodiment, the angle control unit 117 is a pressure roller turning driver, which is used to drive the pressure roller 116 to deflect or not. Therefore, in the flexible substrate adjusting device of this embodiment, the quantity of the pressure roller 116 or the spiral pressure roller 216 may be single or multiple, and the pressure roller 116 or the spiral pressure roller 216 may be used in combination with the angle control unit 117 or separately to achieve flattening or alignment of the flexible substrate 10, and the present disclosure is not limited thereto.

The flexible substrate adjusting device according to the above embodiments of the present disclosure uses a substrate transmission mechanism to transport the flexible substrate and uses the axial friction force generated by the pressure roller to flatten the flexible substrate to reduce wrinkles or adjust the edge position of the flexible substrate to facilitate the processing of the components or circuits on the flexible substrate smoothly. Therefore, the axial friction force generated by the pressure roller could be used for the edge correction and alignment of flexible substrate to achieve accurate alignment.

It will be apparent to those skilled in the art that various modifications and variations could be made to the disclosed embodiments. It is intended that the specification and examples be considered as exemplary only, with a true scope of the disclosure being indicated by the following claims and their equivalents.

What is claimed is:

1. A flexible substrate adjustment device, comprising:
a substrate transmission mechanism having a transmission direction for carrying a first surface of a flexible substrate thereon;
a pressure roller disposed on at least one side of a second surface of the flexible substrate in a non-transmission direction; and
a force applying assembly connected to the pressure roller, providing the pressure roller with a pressure to the flexible substrate, wherein when the flexible substrate moves in the transmission direction, the pressure roller generates an axial friction force in the non-transmission direction with the flexible substrate to adjust flatness of the flexible substrate.

2. The flexible substrate adjusting device according to claim 1, wherein the pressure roller comprises an angle control unit for adjusting a deflection angle of the pressure roller with respect to the transmission direction.

3. The flexible substrate adjusting device according to claim 2, wherein the deflection angle is between 5 degrees and 45 degrees.

4. The flexible substrate adjusting device according to claim 1, wherein the substrate transmission mechanism comprises a step wheel or a flat surface wheel.

5. The flexible substrate adjusting device according to claim 1, wherein the force applying assembly comprises a spring, a pneumatic cylinder, an electromagnetic coil or a motor.

6. The flexible substrate adjusting device according to claim 1, wherein the force applying assembly comprises an actuator for actuating the pressure roller to push down and lift.

7. The flexible substrate adjusting device according to claim 1, wherein the pressure roller comprises a spiral pressure roller, and the spiral pressure roller is disposed on at least one side of the second surface of the flexible substrate in the non-transmission direction.

8. The flexible substrate adjusting device according to claim 7, wherein when the flexible substrate is moved in the transmission direction by the substrate transmission mechanism, the spiral pressure roller is rotated by a pulling force of the flexible substrate.

9. The flexible substrate adjusting device according to claim 7, wherein the spiral pressure roller comprises an angle control unit for adjusting a deflection angle of the spiral pressure roller with respect to the transmission direction.

10. The flexible substrate adjusting device according to claim 1, wherein the pressure roller comprises a plastic wheel, a rubber wheel or a rigid wheel.

11. A flexible substrate adjustment device, comprising:
a substrate transmission mechanism having a transmission direction for carrying a first surface of a flexible substrate thereon;
a pressure roller disposed on at least one side of a second surface of the flexible substrate in a non-transmission direction; and
a force applying assembly connected to the pressure roller, providing the pressure roller with a pressure to the flexible substrate, wherein when the flexible substrate moves in the transmission direction, the pressure roller generates an axial friction force in the non-transmission direction with the flexible substrate to adjust a position of the flexible substrate.

12. The flexible substrate adjusting device according to claim 11, wherein the pressure roller comprises an angle control unit for adjusting a deflection angle of the pressure roller with respect to the transmission direction.

13. The flexible substrate adjusting device according to claim 12, wherein the deflection angle is between 5 degrees and 45 degrees.

14. The flexible substrate adjusting device according to claim 11, wherein the substrate transmission mechanism comprises a step wheel or a flat surface wheel.

15. The flexible substrate adjusting device according to claim 11, wherein the force applying assembly comprises a spring, a pneumatic cylinder, an electromagnetic coil or a motor.

16. The flexible substrate adjusting device according to claim 11, wherein the force applying assembly comprises an actuator for actuating the pressure roller to push down and lift.

17. The flexible substrate adjusting device according to claim 11, wherein the pressure roller comprises a spiral pressure roller, and the spiral pressure roller is disposed on at least one side of the second surface of the flexible substrate in the non-transmission direction.

18. The flexible substrate adjusting device according to claim 17, wherein when the flexible substrate is moved in the transmission direction by the substrate transmission mechanism, the spiral pressure roller is rotated by a pulling force of the flexible substrate.

19. The flexible substrate adjusting device according to claim 17, wherein the spiral pressure roller comprises an angle control unit for adjusting a deflection angle of the spiral pressure roller with respect to the transmission direction.

20. The flexible substrate adjusting device according to claim 11, wherein the pressure roller comprises a plastic wheel, a rubber wheel or a rigid wheel.
